(19) United States
(12) Patent Application Publication
(10) Pub. No.: US 2024/0307918 A1
(43) Pub. Date: Sep. 19, 2024

(54) INTERDIGITATED ULTRASONIC TRANSDUCER

(71) Applicant: UNIVERSITA’ DEGLI STUDI DI FIRENZE, Firenze (IT)

(72) Inventors: Lorenzo CAPINERI, Firenze (IT); Andrea BULLETTI, Arczzo (IT)

(21) Appl. No.: 18/550,987

(22) PCT Filed: Mar. 21, 2022
(86) PCT No.: PCT/IB2022/052533

§ 371 Date: Sep. 18, 2023

(30) Foreign Application Priority Data
Mar. 23, 2021 (IT) 102021000006932

(51) Int. Cl. B06B 1/06; G01N 29/04; G01N 29/24

(52) U.S. Cl. CPC B06B 1/0648; G01N 29/041; G01N 29/2437

(57) ABSTRACT

An interdigitated transducer for generating Lamb waves is described herein, which is characterized by the particular geometry of the electrodes, such a transducer is particularly suitable to be used to make probes for 5 devices for the structural health monitoring of the integrity of materials.

### TECHNICAL FIELD

An interdigitated ultrasonic transducer suitable to be used for the creation of ultrasonic probes of equipment for the non-destructive testing of the integrity of materials is described below. Such non-destructive tests are known to those skilled in the art by the English acronym SHM (Structural Health Monitoring).

### PRIOR ART

It is known that some types of material defects are not detectable, or are in any case difficult to detect, with simple visual inspections. In particular, the phenomena of delamination, weld cracking, corrosion or internal surface erosion cannot be detected with a mere visual check.

To solve such a problem, it is already known to carry out structural health monitoring by examining the propagation of Lamb waves inside the structure to be examined. For example, the presence of discontinuities inside a body gives rise to variations in acoustic impedance which create phenomena of reflection, and attenuation of the wave during the path made through the body examined. In summary, the structural health monitoring by ultrasound is based on the analysis of some features of the reflected and/or transmitted waves inside the structure to be examined. In particular, the attenuation of the received signal with respect to the transmitted signal and the phase difference between the two signals is examined. The structural health monitoring equipment is then equipped with appropriate software which allows the received signals to be interpreted.

In practice, structural health monitoring can be performed using equipment comprising probes which operate either as an ultrasonic pulse emission source, as a return signal receiver, or with separate probes which operate as signal transmitters and receivers. The transmission and/or reception of guided ultrasonic waves can be achieved by devices known as “interdigitated ultrasonic transducers”.

An interdigitated ultrasonic transducer is a reversible device adapted to convert an electrical signal into an ultrasonic signal, or an ultrasonic signal into an electrical signal. Such a conversion is obtained by exploiting the piezoelectric effect of appropriate materials (e.g., piezoelectric crystals or piezoelectric polymers).

In a nutshell, each interdigitated ultrasonic transducer comprises pairs of metallized electrodes, joined to a piezoelectric material. By applying an alternating electrical signal to the electrodes, the piezoelectric material undergoes compression and traction deformations which generate a mechanical wave of frequency equal to the frequency of the electrical signal received. By applying a mechanical wave to the piezoelectric material, it undergoes tensile and compression deformations, producing, by piezoelectric effect, opposite polarities between the electrodes and thus creating an electrical signal with a frequency equal to that of the mechanical wave received.

Interdigitated ultrasonic transducers have such a name because each pair of electrodes comprises portions, roughly or generally comb-shaped, which mutually interpenetrate without touching each other. For example, each electrode can comprise a plurality of parallel strips (so-called “fingers”) electrically joined to a common terminal or bus. The interdigitated electrodes of the electroacoustic transducers can be made, for example, by physical vapour phase deposition of thin films on a piezoelectric material substrate and subsequent optical photolithography or by laser ablation process or thick film screen-printing technique.

Interdigitated transducers are also known by the acronym IDT (Inter Digital Transducer).

The geometry, the relative distance, the dimensional ratios and the dimensions of these comb-shaped electrodes vary according to needs, for example according to the working frequencies or the modes of the Lamb waves to be used.

### Problems of the Prior Art

The currently known devices for non-destructively monitoring the structural conditions of a material by the use of Lamb waves still have some limitations. For example, the portion of volume which can be monitored through a single transducer in a pulse-echo configuration or through a pair of transducers in a pitch-catch configuration is relatively small. When a structure is large, a large number of transducers must be used to monitor the entire structure. Summary of the inventors

The aim of the inventors is to solve, at least in part, the problems of the prior art, and in particular, the problem indicated above. In particular, an objective of the inventors is to propose an interdigitated ultrasonic transducer usable for the structural health monitoring of the integrity of materials. Such an objective is solved in accordance with independent claim 1. Further advantages can be obtained with the additional features of the dependent claims

### LIST OF DRAWINGS

These and other advantages will be better understood by those skilled in the art from the following description and the accompanying drawings, given as non-limiting example, in which:

FIG. 1 shows, schematically, an interdigitated ultrasonic transducer for generating Lamb waves according to a first view;

FIG. 1b is the same view of FIG. 1 in which the extension axes of the transducer fingers are highlighted;

FIG. 2 is a schematic view of a second alternative embodiment of an interdigitated ultrasonic transducer 1;

FIG. 3 is a schematic view of a third alternative embodiment of an interdigitated ultrasonic transducer;

FIG. 4 is a polar diagram showing the radiation lobe obtained with the device of FIG. 1.

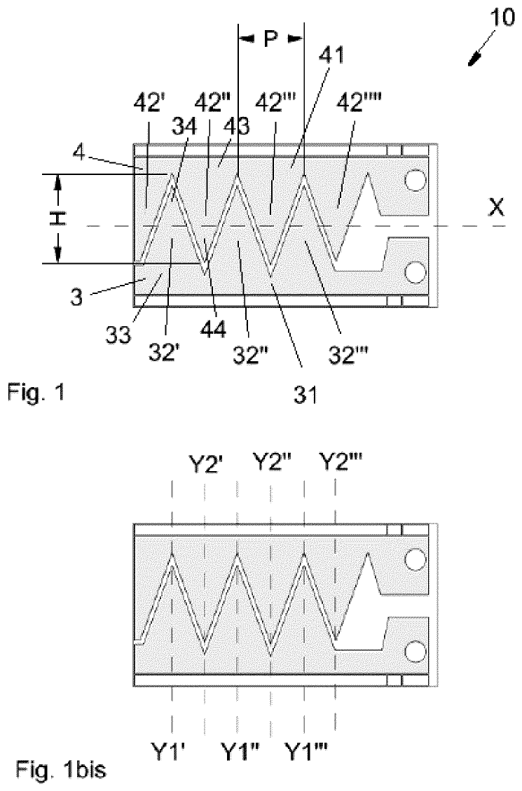

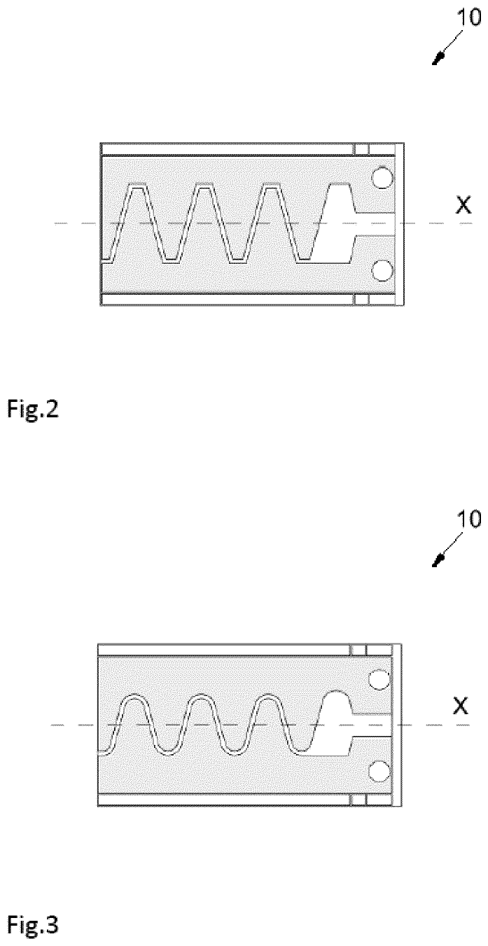

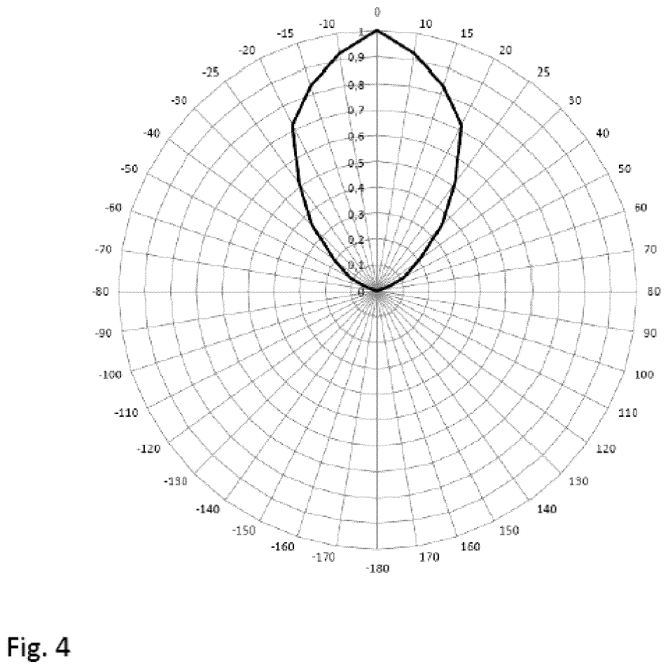

### DETAILED DESCRIPTION

A possible embodiment of an interdigitated ultrasonic transducer will be described below with reference to the accompanying drawings.

With reference to the accompanying drawings, the reference number 10 indicates, as a whole, an ultrasonic transducer interdigitated by ultrasonic waves, in particular Lamb waves.

The transducer 10 comprises a first electrode 3 and a second electrode 4. The first electrode 3 comprises a bus 31 and a plurality of fingers 32′, 32″, 32″ defining a continuous wave profile. The second electrode 4 comprises a bus 41 and a plurality of fingers 42′, 42″, 42′″, 42′″ defining a continuous wave profile. The bus 31 of the first electrode 3 and the bus 41 of the second electrode 4 extend parallel to a first axis X. Each finger 32′, 32″, 32′″ of the first electrode 3 has a proximal part 33, with respect to the bus 31 thereof, and an apical part 34, with respect to the bus 31 thereof. Similarly, each finger 42′, 42″, 42′″, 42″″ of the second electrode 4 has a proximal part 43, with respect to the bus 41 thereof, and an apical part 44, with respect to the bus 41 thereof.

The fingers 32′, 32″, 32′″ of the first electrode 3 have extension axes Y1′, Y1″, Y1′″ parallel to each other and orthogonal to the first axis X. The fingers 42′, 42″, 42′″, 42′″ of the second electrode 4 have extension axes Y2′, Y2″, Y2′″, Y2″″ parallel to each other and orthogonal to the first axis X.

The fingers 32′, 32″, 32′″ of the first electrode 3 and the fingers 42′, 42″, 42′″, 42′″ of the second electrode 4 interpenetrate without touching each other.

The fingers 32′, 32″, 32′″ of the first electrode 3 have a width (dimension transverse to the respective extension axes Y1′, Y1″, Y1′″) which grows monotonously moving from the apical part 34 to the proximal part 33. Similarly, the fingers 42′, 42″, 42′″, 42″″ of the second electrode 4 also have a width (dimension transverse to the extension axes Y2′, Y2″, Y2′″, Y2″″) which grows monotonously directing from said apical part 44 to the proximal part 43.

In some particular embodiments the fingers 32′, 32″, 32′″ of the first electrode 3 have a width which can grow strictly monotonously moving from the apical part 34 to the proximal part 33 and the fingers 42′, 42″, 42′″, 42″″ of the second electrode 4 can have a width which can grow strictly monotonously directing from said apical part 44 to the proximal part 43.

The fingers 32′, 32″, 32′″ of the first electrode 3 and the fingers 42′, 42″, 42′″, 42″″ of the second electrode 4 interpenetrate without touching each other.

The fingers 32′, 32″, 32′″ of the first electrode 3 and the fingers 42′, 42″, 42′″, 42″″ of the second electrode 4 are distributed with a constant pitch P equal, for example, to half the wavelength A of the fundamental frequency at which the transducer 10 is intended to work.

In the illustrated examples, the profiles of the edges of the fingers 32′, 32″, 32′″, 32″″ of the first electrode 3 and of the fingers 42′, 42″, 42′″, 42″″ of the second electrode 4 define a space of substantially constant transverse dimensions.

The geometric solution described above makes it possible to obtain a main radiation lobe which is superior to the solutions of the prior art.

In other words, the substantially tapered shape (which in the illustrated examples is given by the inclination of the edges of the electrodes) allows to obtain a wider radiation lobe with respect to that obtained with conventional rectangular fingers.

This feature of the interdigitated ultrasonic transducer 10 can be advantageously exploited, to create ultrasonic transducers for the structural health monitoring of the integrity of materials. In fact, the particular geometry of the electrodes allows to increase the divergence of the ultrasonic beam and therefore makes it possible to reduce the number of ultrasonic probes necessary to transmit the ultrasonic signal in the structure to be monitored and the number of ultrasonic probes necessary to receive the ultrasonic waves transmitted or reflected through the monitored structure.

The solution described is particularly advantageous for making ultrasonic transducers intended for the structural health monitoring of materials, rolled or not, metal or not, in the form of plates or sheets.

The wavelength A of the Lamb ultrasonic waves used to monitor a rolled material is approximately equal to the thickness of the material, so that the entire thickness of the material can be crossed by the guided ultrasonic wave.

In some possible embodiments of the device 10 the height H of the fingers 32′, 32″. 32′″, 32″″ of the first electrode 3 and the height H of the fingers 42′, 42″, 42′″, 42″″ of the second electrode 4 are equal to each other.

In other embodiments (not shown) the heights of the fingers (32′, 32″, 32′″) of said first electrode (3) can vary.

Similarly, the heights of the fingers (42′, 42″, 42′″, 42″″) of the second electrode (4) can also vary.

In the example shown, the fingers 32′, 32″, 32′″, 32″″ of the first electrode 3 and the fingers 42′, 42″, 42′″, 42″″ of the second electrode 4 define a triangular shape profile, for example of isosceles triangular shape.

The isosceles triangular profile is not binding and can be replaced, for example, by a triangular sawtooth or right triangle profile.

In a second embodiment the fingers 32′, 32″, 32′″, 32″″ and 42′, 42″, 42′″, 42″″ of the two electrodes 3, 4 have a trapezoidal profile, for example in the form of an isosceles trapezium or a rectangular trapezium (the latter example is not illustrated).

In order to avoid thickenings of electric fields and consequent risks of electric shock between the electrodes 3, 4, it is possible to envisage rounding the sharp edges at the apical portions 34, 44 of the fingers 32′, 32″, 32′″, 32″″ and the fingers 42′, 42″, 42′″, 42″″ of the electrodes 3, 4.

In a third embodiment the fingers 32′, 32″, 32′″, 32″″ and 42′, 42″, 42′″, 42″″ of the two electrodes 3, 4 have a profile substantially and/or essentially and/or approximately sine wave-like.

The invention has been described with reference to certain preferred embodiments, but it is understood that technically equivalent modifications can be made without however departing from the scope of protection granted to the present industrial property right.

1. An interdigitated ultrasonic transducer, for generating or receiving guided ultrasonic waves, in particular guided Lamb waves, the transducer comprising:
a first electrode; and
a second electrode,
said first electrode comprising a bus and a plurality of fingers,
said second electrode comprising a bus and a plurality of fingers,
said bus of said first and electrode and said bus of said second electrode extending parallel to a first axis,
each finger of said plurality of fingers of said first electrode having a proximal part, with respect to said bus of said first electrode and an apical part with respect to the bus of said first electrode,
each finger of said plurality of fingers of said second electrode having a proximal part, with respect to the bus of said second electrode and an apical part with respect to the bus of said second electrode,
said plurality of fingers of said first electrode having extension axes parallel to each other and orthogonal to said first axis,
said second plurality of fingers of said second electrode having extension axes parallel to each other and orthogonal to said first axis,
said plurality of fingers of said first electrode and said plurality of fingers of said second electrode interpenetrating without touching each other,
each finger of said plurality of fingers of said first electrode having a monotonously decreasing width directed from said apical part of each finger of said plurality of fingers of said first electrode to said proximal part of each finger of said plurality of fingers of said first electrode,
each finger of said plurality of fingers of said second electrode having a monotonously decreasing width directing from said apical part of each finger of said plurality of fingers of said second electrode to said proximal part of each finger of said plurality of fingers of said second electrode,
said plurality of fingers of said first electrode defining a continuous wave profile,
said plurality of fingers of said second electrode defining a substantially continuous wave profile.

2. The transducer, according to claim 1, wherein said plurality of fingers of said first electrode and said plurality of fingers of said second electrode define a space of substantially constant transverse dimensions.

3. The transducer, according to claim 1, wherein said fingers of said plurality of fingers of said first electrode and said fingers of said plurality of fingers of said second electrode all have a same height.

4. The transducer, according to claim 1, wherein said plurality of fingers of said first electrode define a substantially triangular wave profile and wherein said plurality of fingers of said second electrode define a substantially triangular wave profile.

5. The transducer, according to claim 1, wherein said plurality of fingers of said first electrode define a substantially trapezoidal wave profile and wherein said plurality of fingers of said second electrode define a substantially trapezoidal wave profile.

6. The transducer, according to claim 1, wherein said plurality of fingers of said first electrode define a substantially sine wave profile and wherein said plurality of fingers of said second electrode define a substantially and/or essentially sine wave profile.
